(19) United States
(12) Patent Application Publication
(10) Pub. No.: US 2025/0168971 A1
(43) Pub. Date: May 22, 2025

(54) TRACE WIDTH MODULATION

(71) Applicant: Ampere Computing LLC, Santa Clara, CA (US)

(72) Inventors: Sammy HINDI, San Ramon, CA (US); Chandan BHAT, San Jose, CA (US); Christopher WYLAND, Livermore, CA (US); Surya KONERU, San Jose, CA (US); Shengjun QIN, Sunnyvale, CA (US); Mu-chen TSAI, Bade District, Taoyuan City (TW); Kirk LOWRY, Dublin, CA (US); Lei SHAN, Durham, NC (US); Mysore DIVAKAR, San Jose, CA (US); Quang D. LE, Ho Chi Minh City, Ha Noi (VN); Xiaotong HE, Cupertino, CA (US); Yoham Niranjan PARELKAR, Portland, OR (US); Alex M. GREGORY, Taipei City (TW); Yuyin YU, Linkou District, New Taipei City (TW)

(21) Appl. No.: 18/513,419

(22) Filed: Nov. 17, 2023

(51) Int. Cl. H05K 1/02; G06F 13/38

(52) U.S. Cl. CPC H05K 1/025; G06F 13/38

(57) ABSTRACT

Techniques for trace width modulation are disclosed. In an aspect, a method for trace width modulation may include determining that a region along a length of a trace has an impedance that is different from a target impedance for the trace, and altering a width of at least a portion of the trace within the region to cause the impedance of the trace to be substantially equal to the target impedance of the trace.

### BACKGROUND

### I. Field of the Disclosure

Aspects of the disclosure relate generally to techniques for impedance matching of transmission lines or other electrical traces on printed circuit boards (PCBs) or other circuit substrates.

### II. Background

As used herein, the term “trace” refers to an electrical conductor, usually metal, usually thin, by which a signal or power is routed from one location to another location on a printed circuit board or other circuit substrate. A transmission line is a structure designed to conduct electromagnetic waves in a contained manner. One characteristic of an ideal transmission line is that it has a uniform impedance along its length. A trace may operate as a transmission line if it has been properly designed to maintain a uniform impedance along its length, e.g., by having uniform cross section dimensions along its length and by running parallel to a ground plane or other paired conductor.

As routing density of traces on PCBs increases, and as data rate increases, maintaining uniform transmission line impedance become more difficult and challenging. For example, traces that traverse a field of dense chip connection pads, such as a ball grid array (BGA) footprint, often must be narrowed slightly so that one or more traces can fit in the narrow gap between pads. As a result, a trace may have multiple segments along its length, each segment having a different trace width and thus a different impedance for that segment. The mismatched impedances of different trace segments can cause signal distortion; signal distortion can result in a loss of data integrity; and a loss of data integrity can eventually lead to system failure.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a method for trace width modulation includes determining that a region along a length of a trace has an impedance that is different from a target impedance for the trace; and altering a width of at least a portion of the trace within the region to cause the impedance of the trace to be substantially equal to the target impedance of the trace.

In an aspect, an apparatus includes a printed circuit board having at least one trace having a non-uniform width along its length, wherein the width of the at least one trace is modulated along its length such that an impedance of the trace is substantially equal to a target impedance of the trace.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates an example of a conventional trace that has inductive discontinuities at various locations along its length due to a narrowing of the trace width

FIG. 1B illustrates an implementation of trace width modulation to compensate for the non-uniform impedance that could be caused by a change in inductance over the length of a trace, according to aspects of the disclosure.

FIG. 2A illustrates an example of a conventional trace that has a uniform width down the length of the trace yet has non-uniform impedance caused by capacitance discontinuities.

FIG. 2B illustrates an implementation of width modulation to compensate for the non-uniform impedance that could be caused by a change in capacitance over the length of a trace, according to aspects of the disclosure.

FIG. 3 is a plan view showing various trace width modulation topologies, according to aspects of the disclosure.

FIG. 4 illustrates a conventional trace routing on printed circuit boards (PCBs).

FIG. 5 is a plan view of a portion of a PCB design showing an example of trace width modulation, according to aspects of the disclosure.

FIG. 6 is a plan view showing a comparison of a conventional trace to trace width modulated traces according to various aspects of the disclosure.

FIG. 7 is a flow chart illustrating a process for trace width modulation, according to aspects of the disclosure.

FIG. 8 is a diagram of a system that implements trace width modulation, according to aspects of the disclosure.

### DETAILED DESCRIPTION OF THE DRAWINGS

Techniques for trace width modulation are disclosed. In an aspect, a method for trace width modulation may include: determining that a region along a length of a trace has an impedance that is different from a target impedance for the trace; and altering a width of at least a portion of the trace within the region to cause the impedance of the trace to be substantially equal to the target impedance of the trace. In some aspects, “substantially equal” may mean within a predefined margin of error, which may be ±10%, ±7%, ±5%, etc. The pre-corrected trace may have impedance discontinuities due to inductive discontinuities, capacitive discontinuities, or both.

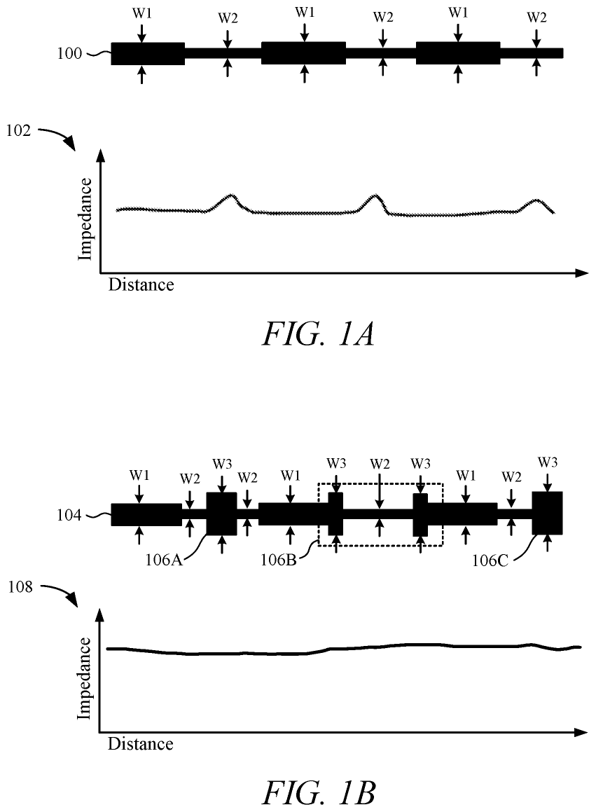

FIG. 1A illustrates an example of a conventional trace 100 that has inductive discontinuities at various locations along its length due to a narrowing of the trace width, such as might be required to route one or more traces through or around obstacles or where trace density is very high and space is limited. In the example shown in FIG. 1A, the trace 100 has a standard width W1 for most of its length. The specific value of W1 is usually chosen so that a trace of width W1 has a target impedance. A common target impedance for PCBs is 50 ohms, but other target impedances may also be used. In the example shown in FIG. 1A, the trace 100 also has three segments where the trace width has been reduced to width W2, which is less than W1. Each narrowed section creates an inductance discontinuity. A graph 102 shows the impedance of the trace 100 over its length (i.e., the distance from its left end). In the example shown in FIG. 1A, the graph 102 shows an increased impedance—e.g., greater than the target impedance—at each section where the trace width was reduced to W2.

FIG. 1B illustrates how trace width modulation can be used to compensate for the non-uniform impedance that could be caused by a change in inductance over the length of a trace. In FIG. 1B, a trace width modulated trace 104 includes sections of width W3 greater than W1, which therefore have less impedance than the target impedance. In the example shown in FIG. 1B, a first section 106A is a segment of width W3 is located between two segments of width W2; a second section 106B includes two segments of width W3 on either side of a segment of width W2; and a third section 106C includes a segment of W3 located at the end of the trace 104 just after a segment of width W2. A graph 108 shows the impedance of the trace 104 over its length (i.e., the distance from its left end), and specifically shows that the trace width modulated portions of the trace 104 have mitigated the increased impedance due to the inductive discontinuities. The exact widths W1, W2, and W3, as well as the lengths of the segments having those widths, will depend on the specific obstacles around which the trace 104 was being routed, as well as specific locations where trace width modulation is possible. Thus, while FIG. 1B shows trace width modulated segments having the same width (W3), it will be understood that in a specific implementation, the wider segments may have other widths, e.g., W4, W5, W6, etc., as needed to produce an average trace impedance at or near the target trace impedance.

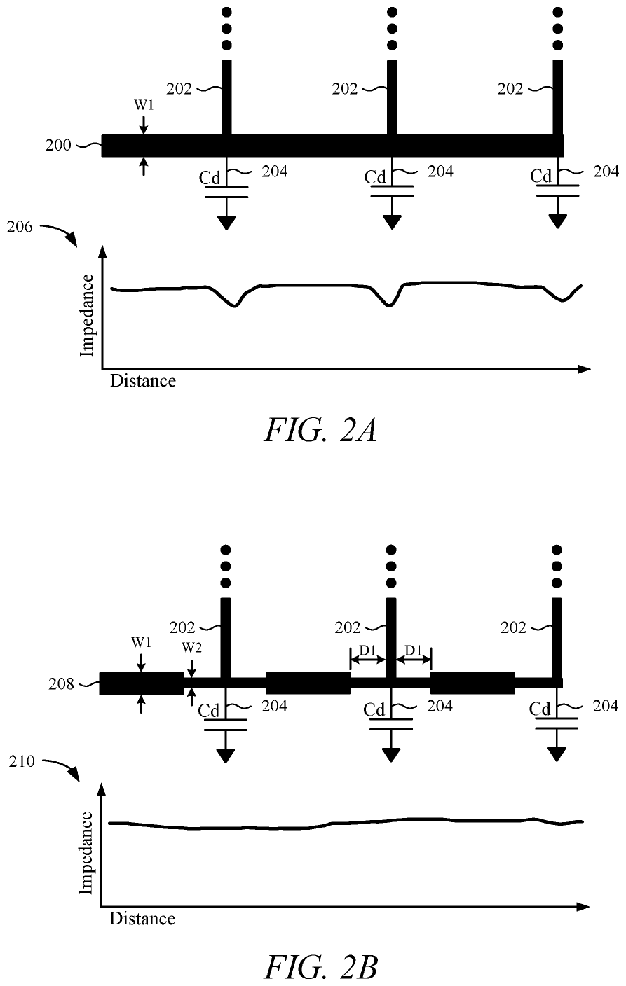

FIG. 2A illustrates an example of a conventional trace 200 that has a uniform width down the length of the trace yet has non-uniform impedance caused by capacitance discontinuities. FIG. 2A illustrates an example of a multidrop trace, which is a main trace 200 of width W1 from which multiple conductors, or “drops”, 202 extend. Each drop 202 creates additional capacitance on the main trace 200, represented in FIG. 2A as a capacitance discontinuity (Cd) 204. A graph 206 shows the impedance of the main trace 200 over its distance. In the example shown in FIG. 2A, the graph 206 shows a decreased impedance at the location of each drop 202.

FIG. 2B illustrates how trace width modulation can be used to compensate for the non-uniform impedance that could be caused by a change in capacitance over the length of a trace. In FIG. 2B, a trace width modulated main trace 208 has the standard width W1 except where each drop 202 connects to the main trace 208 and for some distance D1 along the main trace 208 from the drop 202, where the width is reduced from W1 to W2. A graph 210 shows the impedance of the main trace 208 over its distance, and specifically shows that the trace width modulated portions of the main trace 208 have mitigated the decreased impedance due to the capacitance discontinuities 204.

Thus, trace width modulation may involve increasing the width of a trace, as shown in FIG. 1B, decreasing the width of a trace, as shown in FIG. 2B, or a combination of the two, as needed. For example, a trace width may be reduced to compensate for additional capacitance in a particular segment or reduced to compensate for additional inductance in a particular segment.

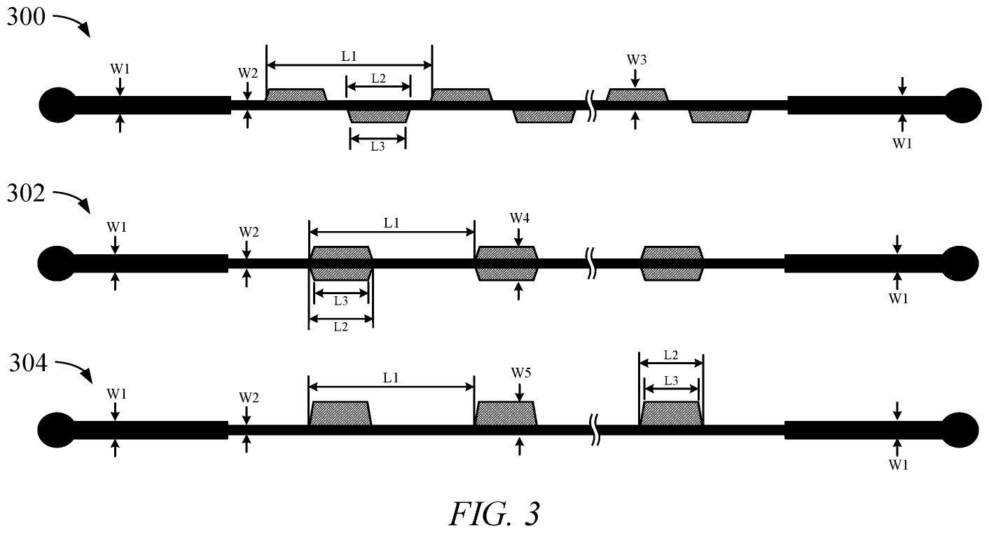

FIG. 3 is a plan view showing various trace width modulation topologies, according to aspects of the disclosure. These examples are illustrative and not limiting. The traces shown in FIG. 3 show an original trace as a black-filled shape and additional extents added to the original trace as a result of trace width modulation as grey-filled shapes. All traces shown in FIG. 3 are traces with a standard width of W1 except for a center segment with a reduced width of W2. In the examples shown in FIG. 3, the pattern of extensions repeats with a period of L1, the edge of the extension closest to the W2-wide center segment has a length of L2, and the edge of the extension farthest from the W2-wide center segment has a length of L3.

As shown in FIG. 3, trace 300 illustrates a topology in which trace extensions are distributed on opposite sides along the length of the narrow portion of the trace 300 in a staggered arrangement, resulting in six portions of width W3 positioned on alternate sides of the W2-wide center segment.

As shown in FIG. 3, trace 302 illustrates a topology in which trace extensions are distributed on opposite sides along the length of the narrow portion of the trace 302 in an aligned arrangement, resulting in three portions of width W4 centered over the W2-wide center segment.

As shown in FIG. 3, trace 304 illustrates a topology in which trace extensions are distributed on the same side along the length of the narrow portion of the trace 304, resulting in three W5 portions of width W5 off-center from the W2-wide center segment.

FIG. 3 illustrates the point that trace width modulation can be implemented in various arrangements. It will be understood that any trace can implement trace width modulation using any of these arrangements, or combinations of these arrangements, in the same trace. It will also be understood that the example dimensions described above are for illustration only and are not limiting.

The specific dimensions of W1, W2, W3, W4, W5, L1, L2, and L3 will depend on factors such as the target impedance, the materials of the trace and the PCB, MCM or other substrate to which the trace is attached, the thickness of the substrate, and other factors that affect the impedance of a trace. The general principle is that the average impedance of the trace over its entire length should be equal to the target impedance, and trace width modulation may be used to provide segments that have impedance that is greater than the target impedance to compensate for other sections of the trace that have impedance that is less than the target impedance, and/or to provide segments that have impedance that is less than the target impedance to compensate other for sections of the trace that have impedance that is greater than the target impedance

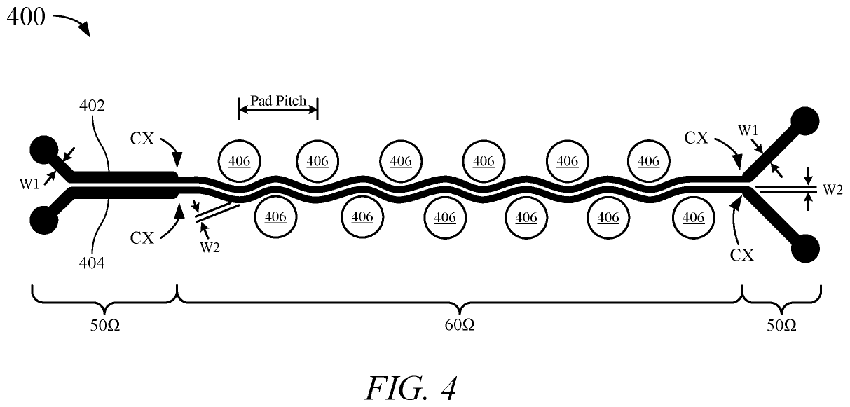

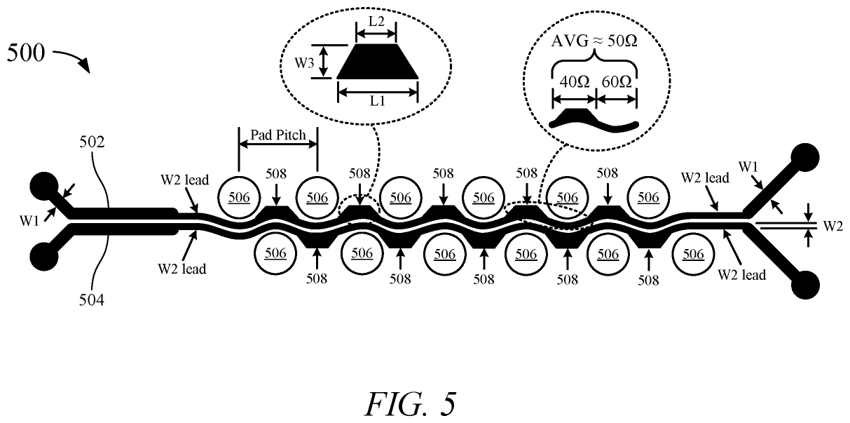

One application of trace width modulation is the design of printed circuit boards (PCBs), multichip modules (MCMs), or other substrates upon which traces may be routed. FIG. 4 illustrates a conventional trace routing, and FIG. 5 illustrates how trace width modulation can mitigate problem(s) associated with such conventional trace routing.

FIG. 4 illustrates a conventional trace routing on printed circuit boards (PCBs). FIG. 4 is a plan view of a portion of a PCB design 400 showing a pair of traces 402 and 404 that are routed around and between obstacles 406, which may be pin pads, ball-grid array (BGA) bonding pads, voids, vias, or other types of obstacles. In the example shown in FIG. 4, each of trace 402 and trace 404 has a first portion that has a width of W1, which gives the first portions a target impedance of 50 ohms, followed by a second portion that has a width of W2 (which is less than W1), followed by a third portion that again has width W1. In this example, the gap between obstacles 406 is too narrow for traces 402 and 404 to be routed there at width W1, which is why traces 402 and 404 have a middle portion of width W2<W1. Since the impedance of a trace is inversely proportional to its width, the portion of the trace having a width of W2 will have higher impedance than the portion of the trace having width W1. In the example shown in FIG. 4, the portion of the trace with width W2 has an impedance of 60 ohms. Thus, it is desirable to have a trace that is narrow enough to allow multiple traces to be routed around BGA bonding pads and other obstacles, yet having an impedance that is equal to, or approximately equal to, the impedance of a normal-width trace.

FIG. 5 is a plan view of a portion of a PCB design 500 showing an example of trace width modulation, according to aspects of the disclosure. In the example shown in FIG. 5 a pair of traces 502 and 504 start having width W1, but are then narrowed to width W2<W1 so that they can be routed around and between obstacles 506. The portions of the trace having a width of W2 will have a higher impedance than the portions of the trace having a width of W1. As shown in FIG. 2, each of trace 502 and trace 504 has a series of regions 508 where the width of the trace has been increased to a width W3>W1. The portions of the trace having a width of W3 will have a lower impedance than the portions of the trace having a width of W1. In some aspects, the dimensions of the regions 508—shown as dimensions W3, W4, and W5 in FIG. 5—are chosen such that when those regions of width W3 are interspersed with the regions of width W2, the average impedance of the trace is approximately equal to the impedance of the trace having a uniform width of W1, e.g., the target impedance. In the simple example illustrated in FIG. 5, the portions of the trace having width W3 have an impedance of 40 ohms and the portions of the trace having width W2 have an impedance of 60 ohms, for an average impedance of 50 ohms. In a more exact example, the higher impedance of the W2 traces between the last obstacle 506 and the end W1 traces—herein referred to as the W2 “leads”—would also be taken into consideration, so that the entire trace averages the target impedance of 50 ohms. In this scenario, the width W3 would be slightly larger so that the impedance of the W3 portions of the trace is less than 40 ohms to compensate for the additional impedance of the W2 leads. It will be understood that the example dimensions and impedances described above are for illustration only and are not limiting.

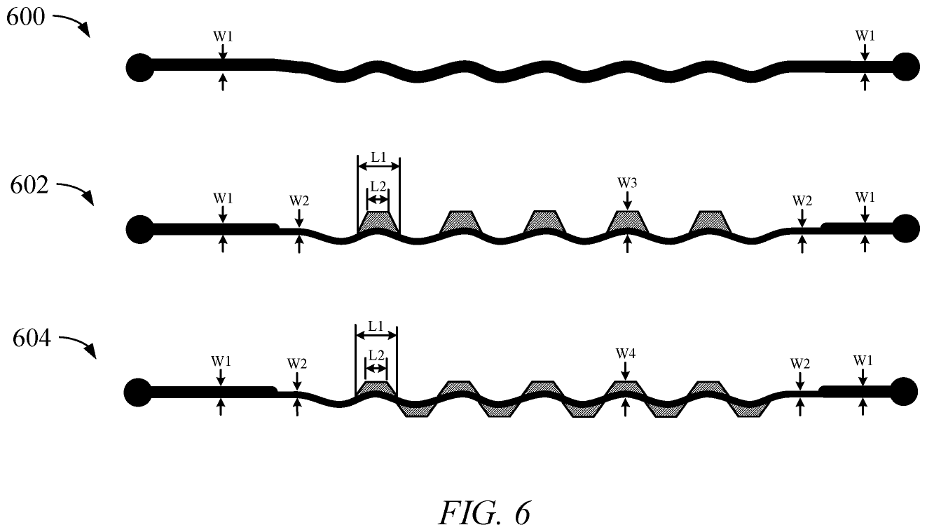

FIG. 6 is a plan view showing a comparison of a conventional trace 600 having a uniform width of W1, a trace width modulated trace 602 according to one aspect of the disclosure, and a trace width modulated trace 604 according to another aspect of the disclosure. The trace width modulated trace 602 has five regions of width W3, a base dimension of L1, and a top dimension of L2. The trace width modulated trace 604 has ten regions of width W4, a base dimension of L1, and a top dimension of L2, where W4<W3. Each of these traces have the same apparent impedance to a signal having a rise time of 30-50 picoseconds. FIG. 6 illustrates the point that the trace width modulation can be successfully implemented by adding a smaller number of larger (e.g., W3) regions or by adding a larger number of smaller (e.g., W4) regions.

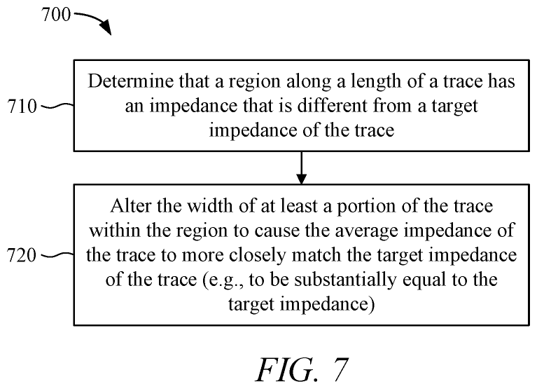

FIG. 7 is a flow chart illustrating a process 700 for trace width modulation, according to aspects of the disclosure. In the example shown in FIG. 7, the process 700 includes, at block 710, determining that a region along a length of a trace has an impedance that is different from a target impedance for the trace.

In the example shown in FIG. 7, the process 700 includes, at block 720, altering a width of at least a portion of the trace within the region to cause the impedance of the trace to more closely match the target impedance of the trace (e.g., to be substantially equal to the target impedance of the trace.

In some aspects, determining that a region along a length of a trace has an impedance that is different from a target impedance for the trace comprises determining that the region has an impedance that is greater than the target impedance. In some aspects, altering the width of at least a portion of the trace within the region comprises increasing the width of the at least a portion of the trace within the region.

In some aspects, determining that a region along a length of a trace has an impedance that is different from a target impedance for the trace comprises determining that the region has an impedance that is less than the target impedance. In some aspects, altering the width of at least a portion of the trace within the region comprises decreasing the width of the at least a portion of the trace within the region.

In some aspects, altering a width of at least a portion of the trace to cause the impedance of the trace to be substantially equal to the target impedance of the trace comprises altering the width of a first portion of the trace within the region so that the impedance of the region is substantially equal to the target impedance of the trace.

In some aspects, altering a width of at least a portion of the trace to cause the impedance of the trace to be substantially equal to the target impedance of the trace comprises altering the width of a first portion of the trace within the region and not altering the width of a second portion of the trace within the region so that the average impedance of the first portion and the second portion is substantially equal to the target impedance of the trace.

In some aspects, altering a width of at least a portion of the trace to cause the impedance of the trace to be substantially equal to the target impedance of the trace comprises increasing the width of a first portion of the trace within the region, decreasing the width of a second portion of the trace within the region, and not changing a third portion of the trace within the region, so that the combined impedance of the first portion, the second portion, and the third portion is substantially equal to the target impedance of the trace.

Process 700 may include additional implementations, such as any single implementation or any combination of implementations described below and/or in connection with one or more other processes described elsewhere herein. Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

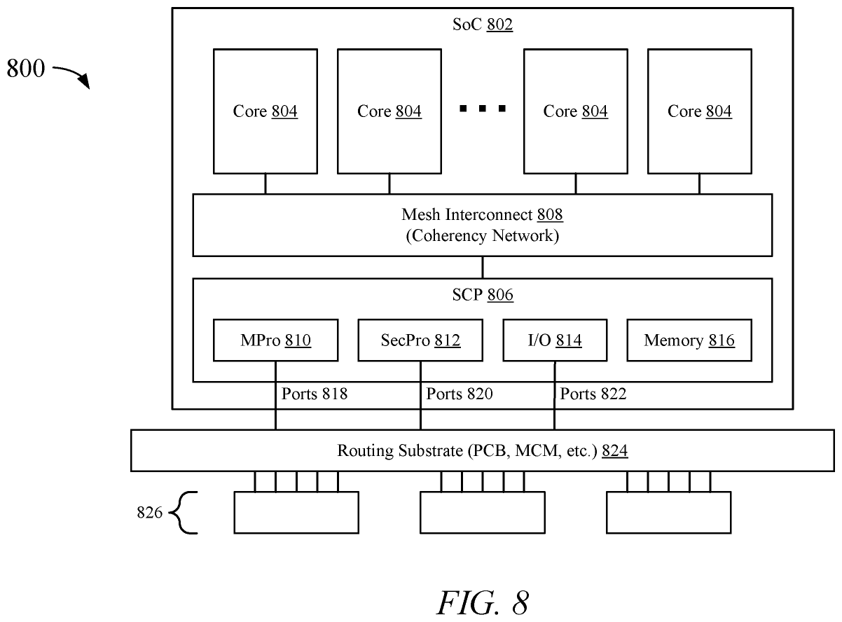

FIG. 8 is a diagram of system 800 that implements trace width modulation, according to aspects of the disclosure. In the example shown in FIG. 8, the system 800 includes a many-core system on a chip (SoC) 802 that implements trace width modulation, according to aspects of the disclosure. The SoC 802 illustrated in FIG. 8 includes a set of processing cores 804 (or simply “cores” 804). The SoC 802 also includes a system control processor (SCP) 806 that handles many of the system management functions of the SoC 802. The cores 804 are connected to the SCP 806 via a mesh interconnect 808 that forms a high-speed bus that couples each of core 804 to the other cores 804 and to other on chip and off-chip resources, including higher levels of memory (e.g., a level three (L3) cache, dual data rate (DDR) memory), peripheral component interconnect express (PCIe) interfaces, and/or other resources.

The SCP 806 may include a variety of system management functions, which may be divided across multiple functional blocks or which may be contained in a single functional block. In the example illustrated in FIG. 8, the system management functions of the SCP 806 are divided between a management processor (MPro) 810 and a security processor (SecPro) 812 coupled to other components of the SoC 802 by the mesh interconnect 808. In the example illustrated in FIG. 8, the SCP 806 further includes an input/output (I/O) block 814 and a shared memory 816 also coupled to other components of the SoC 802 by the mesh interconnect 808. The MPro 810 and the SecPro 812 may connect to one or more off-chip systems via ports 818 and ports 820, respectively, and/or may connect to off-chip systems via the I/O block 814, e.g., via ports 822. The I/O block 814 may connect over ports 822 to external systems and memory (not shown) and connect to the shared memory 816.

In some aspects, one or more of the components described above may be mounted to a routing substrate 824, which may be a PCB, multi-chip module (MCM), etc., to which may be mounted other components 826. In some aspects, the routing substrate 824 may include traces that are routed around various obstacles, some of which may be narrowed in order to fit in the available gaps between obstacles. Some or all of these traces may include trace width modulation as described herein to counteract the change of impedance caused by changes in capacitance and/or inductance. It will be obvious to one of ordinary skill that the trace width modulation techniques described herein are not limited to just traces on the routing substrate 824 but may also be applied to traces on other substrates, including traces within the SoC 802 itself.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill in the art will further appreciate that the various illustrative logical blocks, components, agents, IPs, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, processors, controllers, components, agents, IPs, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium or non-transitory storage media known in the art. An exemplary storage medium is coupled to the processor such that the processor can read information from, and write information to, the storage medium. In the alternative, the storage medium may be integral to the processor. The processor and the storage medium may reside in an ASIC.

Thus, the various aspects described herein may be embodied in a number of different forms, all of which being within the scope of the claimed subject matter. In addition, for each of the aspects described herein, the corresponding form of any such aspects may be described herein as, for example, “logic configured to,” “instructions that when executed perform,” “computer instructions to,” and/or other structural components configured to perform the described action.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A method for trace width modulation, the method comprising:
determining that a region along a length of a trace has an impedance that is different from a target impedance for the trace; and
altering a width of at least a portion of the trace within the region to cause the impedance of the trace to be substantially equal to the target impedance of the trace.

2. The method of claim 1, wherein determining that the region along the length of a trace has an impedance that is different from the target impedance for the trace comprises determining that the region has an impedance that is greater than the target impedance.

3. The method of claim 2, wherein altering the width of the at least a portion of the trace within the region comprises increasing the width of the at least a portion of the trace within the region.

4. The method of claim 1, wherein determining that the region along the length of a trace has an impedance that is different from the target impedance for the trace comprises determining that the region has an impedance that is less than the target impedance.

5. The method of claim 4, wherein altering the width of the at least a portion of the trace within the region comprises decreasing the width of the at least a portion of the trace within the region.

6. The method of claim 1, wherein altering a width of the at least a portion of the trace to cause the impedance of the trace to be substantially equal to the target impedance of the trace comprises altering the width of a first portion of the trace within the region so that the impedance of the region is substantially equal to the target impedance of the trace.

7. The method of claim 1, wherein altering a width of the at least a portion of the trace to cause the impedance of the trace to be substantially equal to the target impedance of the trace comprises altering the width of a first portion of the trace within the region and not altering the width of a second portion of the trace within the region so that an average impedance of the first portion and the second portion is substantially equal to the target impedance of the trace.

8. The method of claim 1, wherein altering a width of the at least a portion of the trace to cause the impedance of the trace to be substantially equal to the target impedance of the trace comprises increasing the width of a first portion of the trace within the region, decreasing the width of a second portion of the trace within the region, and not changing a third portion of the trace within the region, so that a combined impedance of the first portion, the second portion, and the third portion is substantially equal to the target impedance of the trace.

9. The method of claim 1, wherein altering a width of the at least a portion of the trace within the region to cause the impedance of the trace to be substantially equal to the target impedance of the trace comprises causing the impedance of the trace to be equal to the target impedance within a target margin of error.

10. The method of claim 9, wherein the target margin of error comprises plus or minus ten percent.

11. The method of claim 9, wherein the target margin of error comprises plus or minus seven percent.

12. The method of claim 9, wherein the target margin of error comprises plus or minus five percent.

13. The method of claim 1, wherein altering a width of the at least a portion of the trace within the region comprises altering the width of a plurality of portions of the trace within the region.

14. An apparatus, comprising:
a printed circuit board having at least one trace having a non-uniform width along its length,
wherein a width of the at least one trace is modulated along its length such that an impedance of the trace is substantially equal to a target impedance of the trace.

15. The apparatus of claim 14, wherein a first portion of the trace has a first width and a second portion of the trace has a second width different from the first width and wherein an average of the impedance of the first portion and the impedance of the second portion is substantially equal to the target impedance of the trace.

16. The apparatus of claim 14,
wherein a first portion of the trace has a first width and a first impedance equal to the target impedance,
wherein a second portion of the trace has a second width greater than the first width and a second impedance less than the target impedance,
wherein a third portion of the trace has a third width less than the first width and a third impedance greater than the target impedance, and
wherein a combined impedance of the first portion, the second portion, and the third portion is substantially equal to the target impedance of the trace.

17. The apparatus of claim 16, wherein an average of the second impedance and the third impedance is substantially equal to the target impedance of the trace.

18. The apparatus of claim 14, wherein the impedance of the trace is within plus or minus ten percent of the target impedance.

19. The apparatus of claim 14, wherein the impedance of the trace is within plus or minus seven percent of the target impedance.

20. The apparatus of claim 14, wherein the impedance of the trace is within plus or minus five percent of the target impedance.

21. The apparatus of claim 14, wherein a width of the at least one trace is modulated at a plurality of locations along its length.
